(19) United States
(12) Patent Application Publication
(10) Pub. No.: US 2003/0033712 A1
(43) Pub. Date: Feb. 20, 2003

(54) Method for assembling micro devices and related apparatus

(76) Inventor: Robert W. Johnstone, Burnaby (CA)

Correspondence Address: OYEN, WIGGS, GREEN & MUTALA, 480 - THE STATION, 601 WEST CORDOVA STREET, VANCOUVER, BC, V6B 1G1, CA

(21) Appl. No.: 10/212,255

(22) Filed: Aug. 6, 2002

Related U.S. Application Data
(60) Provisional application No. 60/309,793, filed on Aug. 6, 2001.

(51) Int. Cl. H01R 43/00; H05K 3/30

(52) U.S. Cl. 29/832; 29/825

(57) ABSTRACT

A method for making a three dimensional structure comprises on a substrate providing a plurality of parts hingedly coupled to the substrate; pivoting the parts into positions in which the parts can be inter-engaged by applying electrostatic forces to the parts; and, engaging the parts with one another to provide a three dimensional structure.

### TECHNICAL FIELD

This technology applies to surface micro-machining technology. In particular, the invention relates to methods for manufacturing miniature structures.

### BACKGROUND

Prior art in the assembly of raised uses prober stations. Prober stations are a common tool in the microelectronics industry, and comprise of several fine needles connected to micro-actuators. While the standard use of these stations is to make on-chip electrical connections, micro-fabrication groups have used the stations to mechanically move parts of miniature structures into place. This can be tedious and time consuming.

### SUMMARY OF INVENTION

The invention relates to a process for assembling surface micro-machined parts into larger structures. The process involves forming parts which are connected to a surface of a substrate by micromechanical hinges. The hinges permit the parts to rotate about an axis of the hinge. The substrate is, for example, a silicon wafer or chip. The parts are preferably in the form of flattened plates having a desired shape.

Various structures may be used to provide the hinges. Currently, there are three types of hinges used in surface micro-machining: torsion hinges, staple hinges and scissor hinges. The technique will work with any type of hinge that allows components to rotate off of the surface. The choice of a particular hinge design will depend on the hinge types' relative manufacturability and whether or not the design requires additional degrees of freedom.

The parts are each connected to a voltage source. Different parts, or groups of parts are connected to different voltage sources so that the electrical potential being applied to the different parts or groups of parts can be individually varied. In addition to the parts on the substrate, an electrically conductive plate (or plates) is provided.

The method of the invention involves positioning selected parts relative to one another by applying voltages to the parts and plates so that the selected parts pivot about their hinges into the desired relative positions.

Voltages are applied to the on-chip parts and off-chip plate(s). By selecting appropriate voltages the parts will be attracted to each other. The distances and the relative voltages between parts determine the amount of electrostatic attraction. The plate(s) are positioned over the chip and so that they will provide a lifting force to the on-chip parts when voltage is applied. With sufficient voltage, the electrostatic attractive forces exerted on the parts will cause the parts to pivot away from the surface of the substrate. When the parts are raised, voltages can be applied between selected ones of the raised parts. The electrostatic attraction will then pull the on-chip parts together. The parts are shaped so that they fit together to form a desired structure. One part may have a mating section which receives an edge of another part. With properly designed hinges and mating section, the parts can be assembled into larger structures.

Mating section design depends on the type of mating required and the direction of assembly. Where the mating is suppose to hold the components in fixed contact and the parts are perpendicular to each other, as shown, for example, in FIG. 4, a mating section as shown in FIG. 1 can be provided on a first part. The wide opening at the top is designed to catch the edge of a second part during assembly and guide the parts together. The narrow section has the same width as the thickness of the part which it receives. Thus, when the second component is received edgewise within the narrow slot the two parts are fixed together laterally.

A sample assembly sequence illustrates the methods of the invention. FIG. 2 depicts the parts necessary for a surface micro-machined mirror. Notice the orientation of the hinges on the parts. Typically, staple hinges will be used. A single plate (not shown) is suspended over the chip and grounded. This ground plate is parallel to the wafer surface.

All three on-chip parts are connected to independent voltage sources, which are brought to a large enough value so that the parts lift from the wafer surface. With sufficient voltage, they should move to positions as illustrated in FIG. 3. As the ground plane is parallel to the wafer surface, the parts should end up substantially perpendicular to the wafer surface.

The voltage applied to the two outside parts (vertical supports) is then returned to the ground potential. The vertical supports are no longer attracted to the ground plane, but are now attracted to the mirror. The vertical supports therefore fall inwardly toward the mirror (which remains oriented perpendicularly to the surface). The mating sections at the tip of the vertical supports then connect with and mate with the mirror.

Assembly is complete and the voltages sources can be removed.

In addition to the methods described above, the invention relates to structures adapted to be assembled using the methods of the invention, the structures including a number of parts hinged to a substrate and connectable to voltage sources for assembly into structures as described above.

### BRIEF DESCRIPTION OF DRAWINGS

In figures which illustrate non-limiting embodiments of the invention:

FIG. 1 is a plan view of an example part;

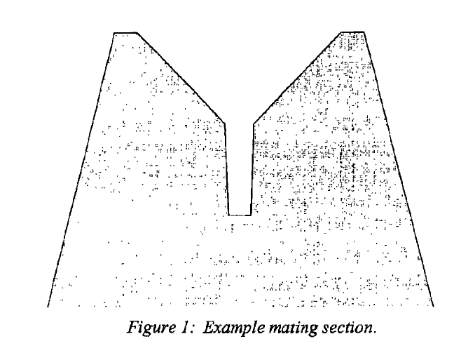

FIG. 2 is a plan view of a number of parts on a substrate waiting to be assembled;

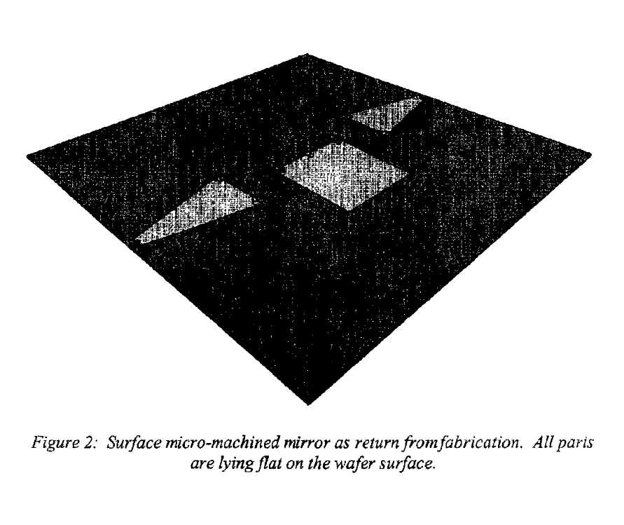

FIG. 3 is an isometric view of the parts of FIG. 2 being pivoted away from the substrate into positions in which they can be inter-changed; and,

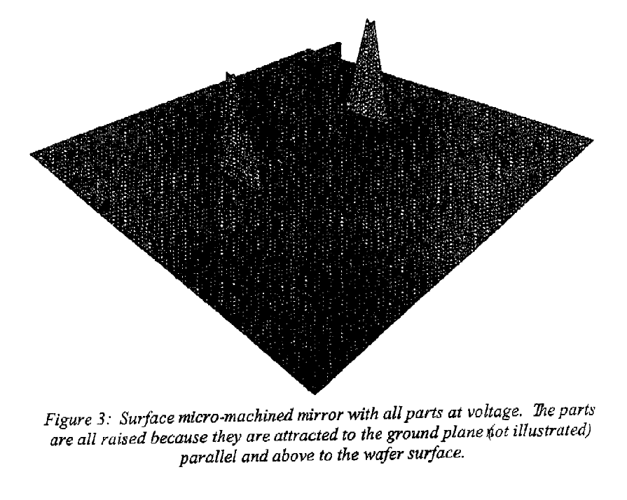

FIG. 4 is an isometric view of the parts of FIG. 3 engaged with one another to provide a three dimensional structure.

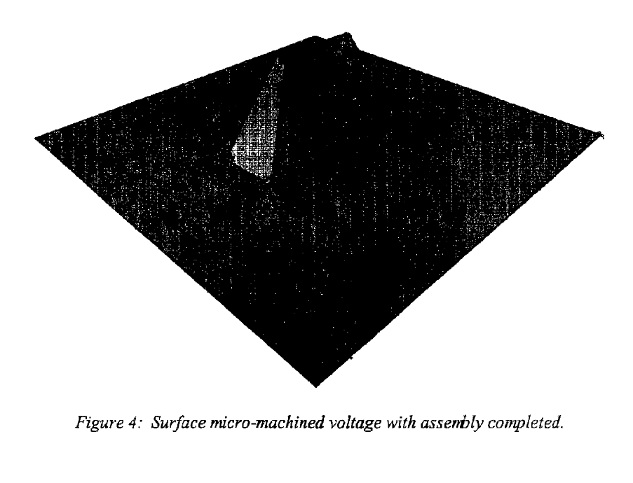

### DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive, sense.

One of the main difficulties with surface micro-machining technology is the thickness limitation of the parts that are manufacturable. Hinged parts can be assembled into larger structures with significant out-of-plane dimensions by use of the methods of this invention. Preferred embodiments of the invention provide parallel and automated assembly of miniature structures.

Parallel assembly refers to the fact that all structures on a chip can be assembled simultaneously.

As will be apparent to those skilled in the art in the light of the foregoing disclosure, many alterations and modifications are possible in the practice of this invention without departing from the spirit or scope thereof. Accordingly, the scope of the invention is to be construed in accordance with the substance defined by the following claims.

What is claimed is:

1. A method for making a three dimensional structure comprising:
a) on a substrate providing a plurality of parts hingedly coupled to the substrate;
b) pivoting the parts into positions in which the parts can be inter-engaged by applying electrostatic forces to the parts; and,
c) engaging the parts with one another to provide a three dimensional structure.
